(19) United States
(12) Patent Application Publication
(10) Pub. No.: US 2024/0324176 A1
(43) Pub. Date: Sep. 26, 2024

(54) MEMORY DEVICE AND MANUFACTURING METHOD THEREOF

(71) Applicant: Winbond Electronics Corp., Taichung City (TW)

(72) Inventor: Shou-Te Wang, Taichung City (TW)

(73) Assignee: Winbond Electronics Corp., Taichung City (TW)

(21) Appl. No.: 18/325,008

(22) Filed: May 29, 2023

(30) Foreign Application Priority Data
Mar. 24, 2023 (TW) 112111166

(51) Int. Cl. H10B 12/00

(52) U.S. Cl. CPC H10B 12/315; H10B 12/0335; H10B 12/053; H10B 12/34; H10B 12/482

(57) ABSTRACT

A memory device and its manufacturing method are provided. Memory cells of the memory device arranged in an array respectively include an access transistor and a storage capacitor connected to the access transistor through a capacitor contact (CC) structure. Based on a specific arrangement manner, the CC structures are closely arranged in pairs. Each pair of the CC structures are connected to a neighboring access transistor and isolated from each other through an isolation wall. Each isolation wall includes an inner wall and outer walls located on opposite sides of the inner wall. The inner wall has sufficient etch selectivity with respect to the outer walls. Despite etchants or reactive substances inevitably consume the outer walls during manufacturing, the etchants or the reactive substances may be blocked by the inner wall without penetrating the entire isolation wall. Therefore, an electrical isolation between the neighboring CC structures may be guaranteed.

### CROSS-REFERENCE TO RELATED APPLICATION

This application claims the priority benefit of Taiwan patent application serial no. 112111166, filed on Mar. 24, 2023. The entirety of the above-mentioned patent application is hereby incorporated by reference herein and made a part of this specification.

### BACKGROUND

### Technical Field

The disclosure relates to a memory device and a manufacturing method thereof; more particularly, the disclosure relates to a dynamic random access memory (DRAM) device and a manufacturing method thereof.

### Description of Related Art

A dynamic random access memory (DRAM) is a volatile memory which has been widely applied. Each DRAM cell includes an access transistor and a storage capacitor connected to the access transistor. With the development of a manufacturing process of the DRAM, an integration density of the DRAM continues to increase. Such an increase in the integration density includes shortening pitches of active regions of the access transistors. Thereby, two capacitor contact (CC) structures configured to connect the adjacent access transistors to the corresponding storage capacitors become very close, thus leading to a short circuit issue.

### SUMMARY

An embodiment of the disclosure provides a memory device that includes a semiconductor substrate, a first word line and a second word line, a first capacitor contact (CC) structure and a second CC structure, and an isolation wall. The semiconductor substrate has a first active region and a second active region separated by a trench isolation structure. The first word line and the second word line are embedded in the semiconductor substrate, where the first word line and the second word line are spaced from each other in a first direction and extend along a second direction substantially orthogonal to the first direction and penetrate the first active region and the second active region spaced from each other in the second direction The first CC structure and a second CC structure are disposed on the semiconductor substrate and located on opposite sides of the first word line and the second word line, where the first CC structure overlaps and is connected to the first active region, the second CC structure overlaps and is electrically connected to the second active region, and the first CC structure and the second CC structure are arranged along the first direction. Two opposite sides of the isolation wall contact the first CC structure and the second CC structure, and the isolation wall includes an inner wall and outer walls covering two opposite sides of the inner wall, where an insulation material of the inner wall has etch selectivity with respect to an insulation material of the outer walls.

Another embodiment of the disclosure provides a manufacturing method of a memory device, and the manufacturing method includes following steps. A trench isolation structure is formed in a semiconductor substrate to define a first active region and a second active region spaced from each other. A first word line and a second word line are formed in the semiconductor substrate, where the first word line and the second word line are spaced from each other in a first direction and, along a second direction substantially orthogonal to the first direction, penetrate the first active region and the second active region spaced from each other in the second direction. A first CC structure and a second CC structure are formed on the semiconductor substrate, where the first word line and the second word line extend between the first CC structure and the second CC structure, the first CC structure overlaps and is connected to the first active region, the second CC structure overlaps and is connected to the second active region, and the first CC structure and the second CC structure are arranged along the first direction. An isolation wall is set on the semiconductor substrate, where two opposite sides of the isolation wall contact the first CC structure and the second CC structure, the isolation wall includes an inner wall and outer walls covering two opposite sides of the inner wall, and an insulation material of the inner wall has etch selectivity with respect to an insulation material of the outer walls.

To make the above more comprehensible, several embodiments accompanied with drawings are described in detail as follows.

### BRIEF DESCRIPTION OF THE DRAWING

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a schematic plane view illustrating a portion of a memory device according to some embodiments of the disclosure.

FIG. 1B is a schematic cross-sectional view taken along a line X1-X1′ depicted in FIG. 1A.

FIG. 1C is a schematic cross-sectional view taken along a line X2-X2′ depicted in FIG. 1A.

FIG. 2 is a flowchart illustrating a method of forming the structure depicted in FIG. 1A to FIG. 1C according to some embodiments of the disclosure.

FIG. 3A to FIG. 3V are schematic cross-sectional views illustrating an intermediate structure during a period in which the method depicted in FIG. 2 is performed.

### DESCRIPTION OF THE EMBODIMENTS

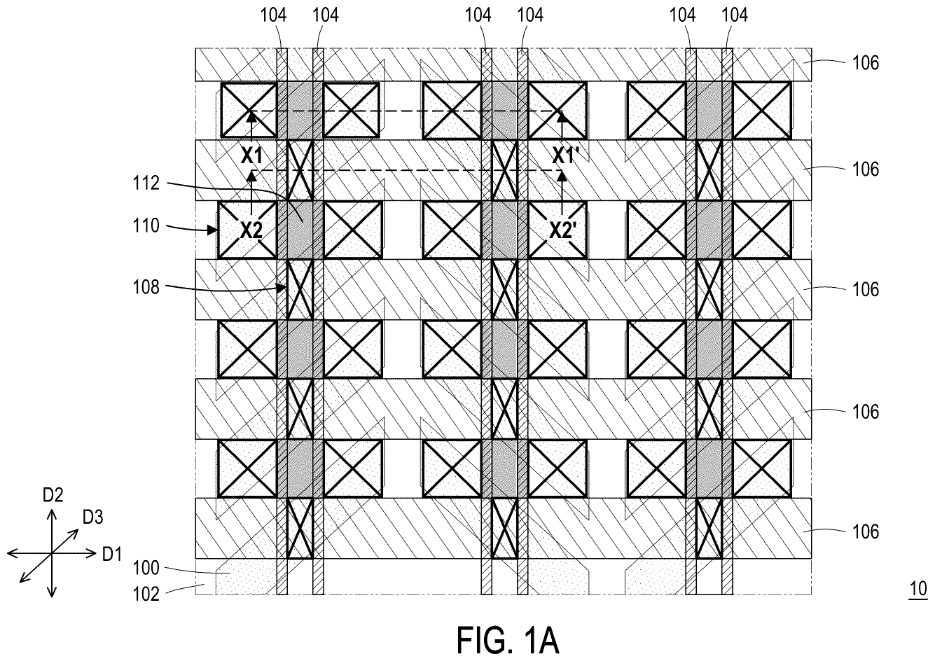

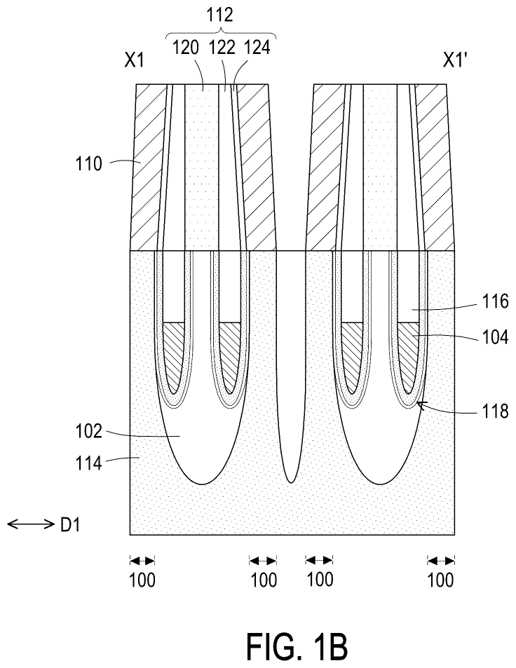

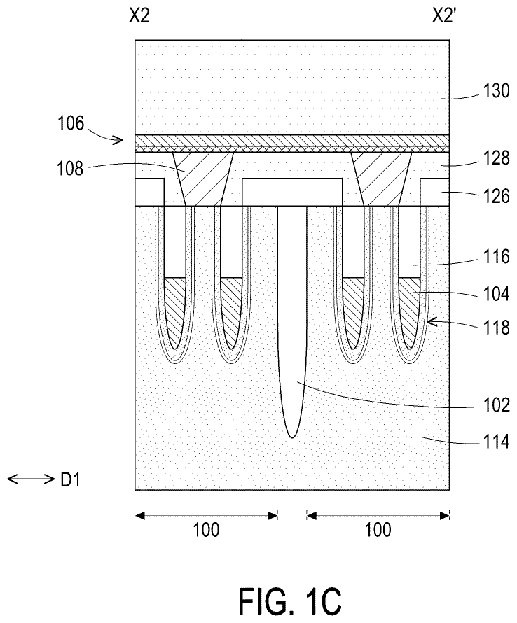

FIG. 1A is a schematic plane view illustrating a portion of a memory device 10 according to some embodiments of the disclosure. A memory device 10 is a DRAM array that includes a plurality of DRAM cells. Each DRAM cell includes an access transistor and a storage capacitor connected to the access transistor. To clearly illustrate a CC structure configured to connect the access transistor to the storage capacitor, FIG. 1A does not show the storage capacitor covering the CC structure. In addition, FIG. 1A does not show most of the insulation components. At least one of the insulation components will be described with reference to FIG. 1B and FIG. 1C.

With reference to FIG. 1A, the memory device 10 includes a plurality of active regions 100. Each of the active regions 100 may be a portion of a semiconductor substrate (e.g., a semiconductor substrate 114 which will be described with reference to FIG. 1B and FIG. 1C). A trench isolation structure 102 formed in the semiconductor substrate laterally surrounds each of the active regions 100, so that the neighboring active regions 100 are electrically isolated from each other.

The active regions 100 are arranged in an array along a direction D1 and a direction D2 which intersects (e.g., is orthogonal to) the direction D1. In addition, each of the active regions 100 may extend along a direction D3 intersecting the direction D1 and the direction D2. Moreover, the active regions 100 that are arranged in each column and along the direction D2 may be mirror-symmetrical to the active regions 100 in the neighboring column.

Along the direction D2, a plurality of word lines 104 penetrate the active regions 100 arranged in an array. The access transistor of each DRAM cell is defined to be at an intersection of one of the word lines 104 and one of the active regions 100. For each access transistor, the word line 104 passing through the access transistor serves used as a gate of the access transistor, and portions of the active region 100 which are located on two sides of the word line 104 and on which the access transistor is located serve as a drain and a source of the access transistor. In order to allow the two access transistors to share one active region 100, each of the active regions 100 intersects a pair of word lines 104. As such, a portion of each active region 100 located between the two word lines 104 intersecting the active region 100 may serve as a common drain/source of the two access transistors sharing the active region 100.

A plurality of bit lines 106 extend above the semiconductor substrate along the direction D1 and intersect one row of active regions 100, respectively. The portion of each active region 100 acting as the common drain/source may be connected to an overlying bit line 106 through a bit line contact structure 108. As mentioned above, the portion of each active region 100 acting as the common drain/source may be the portion located between the two word lines 104 intersecting the active region 100. Therefore, each active region 100 may be overlapped with an overlying bit line contact structure 108 and an overlying bit line 106 through the portion located between the two word lines 104 intersecting the active region 100.

On the other hand, the portions of each active region 100 which are located on two sides of the word line 104 intersecting the active region 100 are respectively connected to the overlying storage capacitor (not shown) through a CC structure 110. In other words, each active region 100 and two CC structures 110 are overlapped. Since each active region 100 extends along the direction D3 intersecting the direction D1 (the row direction) and the direction D2 (the column direction), the two CC structures 110 overlapping the active region 100 are also arranged along the direction D3. In addition, the active regions 100 in each column are mirror-symmetrical to the active regions 100 in the adjacent column, so that all CC structures 110 may be arranged in an array along the direction D1 and the direction D2. In each row, the CC structures 110 are arranged in pairs. Each pair of the CC structures 110 overlap the neighboring active regions 100 in the same column and adjoin each other.

A plurality of isolation walls 112 arranged in an array are configured to provide electrical isolation between the CC structures 110. Each isolation wall 112 is disposed on a pair of the neighboring CC structures 110 in the same row and may overlap two word lines 104 between the pair of the contact structures 110. Since the pair of the neighboring CC structures 110 in the same row overlap the neighboring active regions 100 in the same column, the isolation wall 112 located between each pair of the CC structures 110 overlaps the trench isolation structure 102 extending between the active regions 100. In addition, each isolation wall 112 is laterally spaced from the neighboring isolation walls 112. As mentioned above, the CC structures 110 are arranged in an array along the direction D1 and the direction D2. As such, the isolation wall 112 respectively located between the neighboring CC structures 110 arranged in pairs in each row is also arranged in an array along the direction D1 and the direction D2. The isolation wall 112 in each column may be alternately arranged with a plurality of bit line contact structures 108, and two CC structures 110 are disposed between the neighboring isolation walls 112 in each row.

FIG. 1B is a schematic cross-sectional view taken along a line X1-X1′ depicted in FIG. 1A, and FIG. 1C is a schematic cross-sectional view taken along a line X2-X2′ depicted in FIG. 1A. With reference to FIG. 1A and FIG. 1B, the trench isolation structure 102 extends from a top surface of the semiconductor substrate 114 into the semiconductor substrate 114 and defines a plurality of active regions 100. It can be seen from FIG. 1B that the word lines 104 are embedded in the semiconductor substrate 114 and may pass through the trench isolation structure 102. In addition, the word lines 104 may be formed at bottoms of trenches deep into the semiconductor substrate 114, and upper portions of these trenches are filled with insulation plugs 116. Besides, an inner surface of each trench may be lined with a gate dielectric layer 118, so that the word line 104 and the insulation plug 116 therein are covered by the gate dielectric layer 118.

FIG. 1B also shows two pairs of the CC structures 110 in the same row. The CC structures 110 are located above the semiconductor substrate 114. It can be seen from FIG. 1A and FIG. 1B that each pair of the CC structures 110 overlap two neighboring active regions 100 laterally separated by a portion of the trench isolation structure 102, and the isolation wall 112 configured for separation covers the portion of the trench isolation structure 102. In addition, a pair of the word lines 104 below each isolation wall 112 extend and pass through the trench isolation structure 102, so that each isolation wall 112 also overlaps a pair of the word lines 104 and the surrounding insulation plugs 116 and the surrounding gate dielectric layers 118.

Each isolation wall 112 includes an inner wall 120 and transistors. Thereby outer walls 122 covering two opposite sides of the inner wall 120, so that the inner wall 120 laterally contacts a pair of the CC structures 110 through the outer walls 122 on both sides of the inner wall 120. The inner wall 120 and the outer walls 122 are made of different insulation materials. In particular, the inner wall 120 has sufficient etch selectivity with respect to the outer walls 122, so that etchants or reactive substances, even if they enter the outer walls 122 during manufacturing, may be blocked by the inner wall 120 without penetrating the entire isolation wall 112. As such, the electrical isolation between the neighboring CC structures 110 may be guaranteed more effectively. In other words, the neighboring DRAM cells may be prevented from interfering with each other. As an example, a material of the outer walls 122 may include silicon oxide, while a material of the inner wall 120 may include silicon nitride. However, people skilled in the pertinent art may change the combination of the materials of the inner wall 120 and the outer walls 122 according to the manufacturing requirements, as long as the material of the inner wall 120 has sufficient ability to block the etchants that are able to etch the outer walls 122.

In some embodiments, each isolation wall 112 further includes a liner layer 124 that covers outer surfaces of the outer walls 122. In these embodiments, the inner wall 120 of each isolation wall 112 is in lateral contact with a pair of the CC structures 110 through the outer walls 122 and the liner layer 124. The liner layer 124 is also made of an insulation material. For instance, a material of the liner layer 124 may be silicon oxide.

In some embodiments, a top surface of the inner wall 120 and top surfaces of the outer walls 122 (and a top surface of the liner layer 124) are substantially coplanar and collectively define a top surface of the isolation wall 112. Besides, in some embodiments, the top surface of the isolation wall 112 is substantially coplanar with a top surface of the CC structure 110.

With reference to FIG. 1A and FIG. 1C, each active region 100 is penetrated by two word lines 104 (and the surrounding insulation plug 116 and the surrounding gate dielectric layer 118) intersecting the active region 100. A portion of each active region 100 located between the two word lines 104 intersecting the active region 100 may serve to define the common drain/source of the two access transistors located in the active region 100 and may be connected to one of the bit lines 106 through the overlying bit line contact structure 108. In some embodiments, an insulation pattern 126 may be disposed between the neighboring bit line contact structures 108, the bit line contact structures 108 and the insulation pattern 126 are embedded in a dielectric layer 128, and the bit line 106 extends on the dielectric layer 128. Although the bit line 106 is shown to have a double-layer structure, the bit line 106 may also have a single-layer structure or a multi-layer structure having at least three layers. Additionally, in some embodiments, the bit line 106 is covered by another dielectric layer 130.

It may be seen from FIG. 1B and FIG. 1C that a top surface of the bit line 106 may be lower than the top surfaces of the CC structures 110 and the top surface of the isolation wall 112, and the bit line contact structures 108 are located below the bit line 106.

Although more cross-sectional views are not provided for description, more insulation features may be disposed on the semiconductor substrate 114 to ensure the electrical insulation between the bit line contact structures 108, the CC structures 110, and the bit line 106. In addition, although not shown in the drawings, the CC structures 110 are respectively connected to the overlying storage capacitors. In some embodiments, all of the storage capacitors may have respective lower electrodes but share the dielectric layer and the upper electrode.

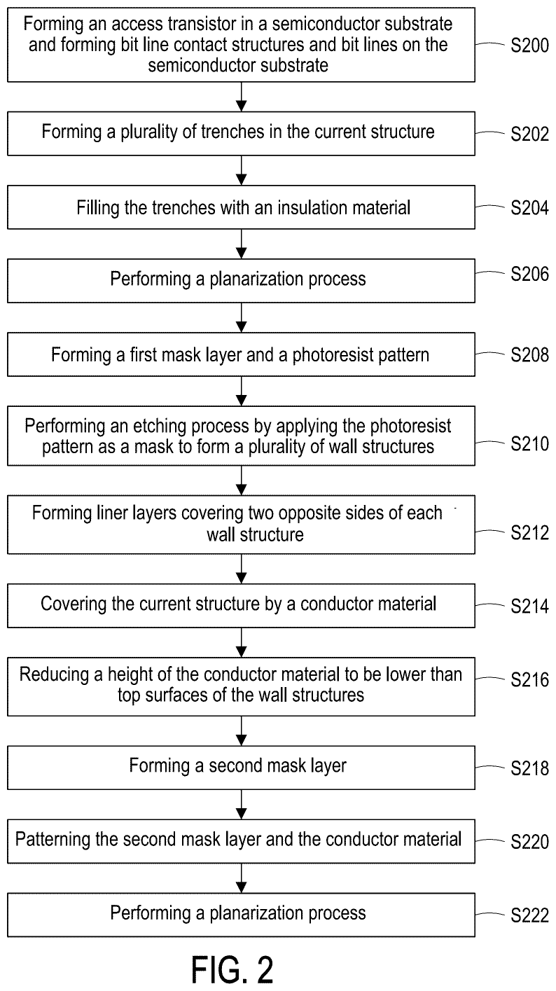

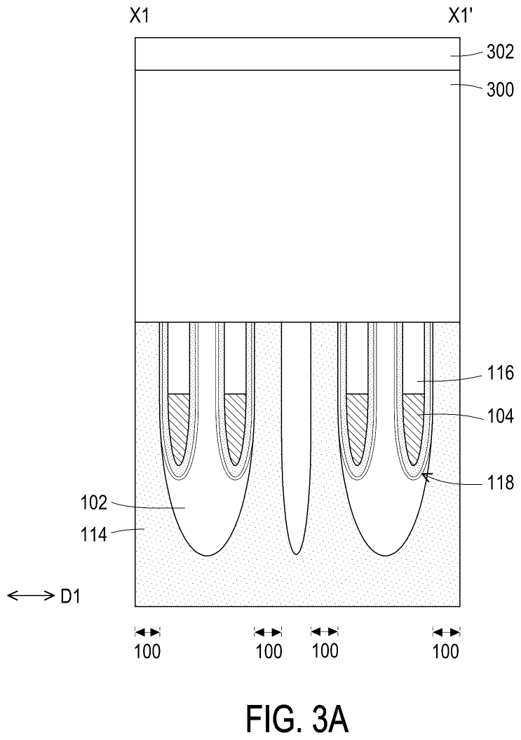

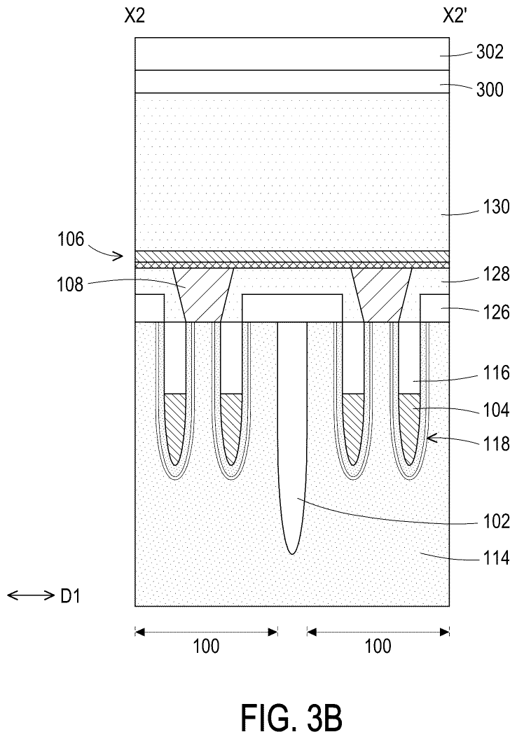

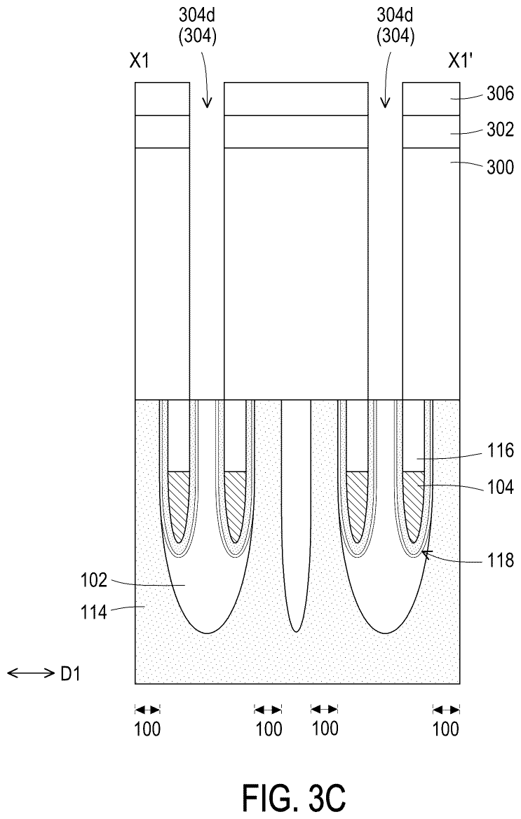

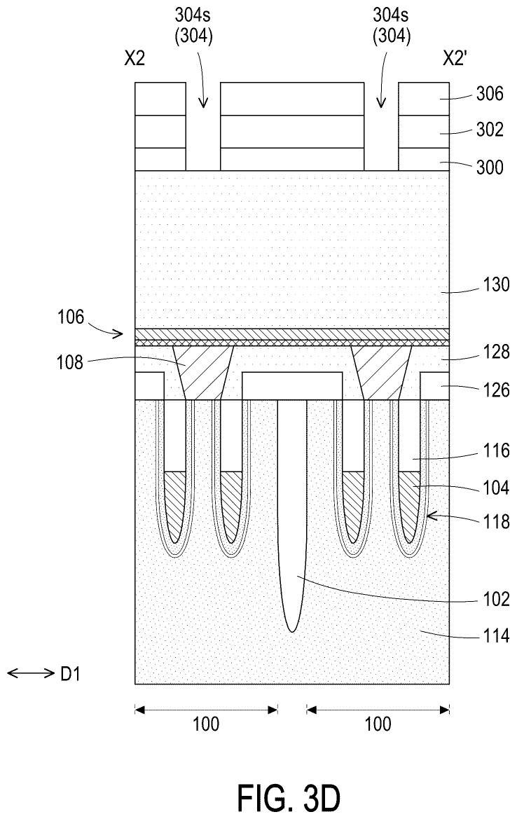

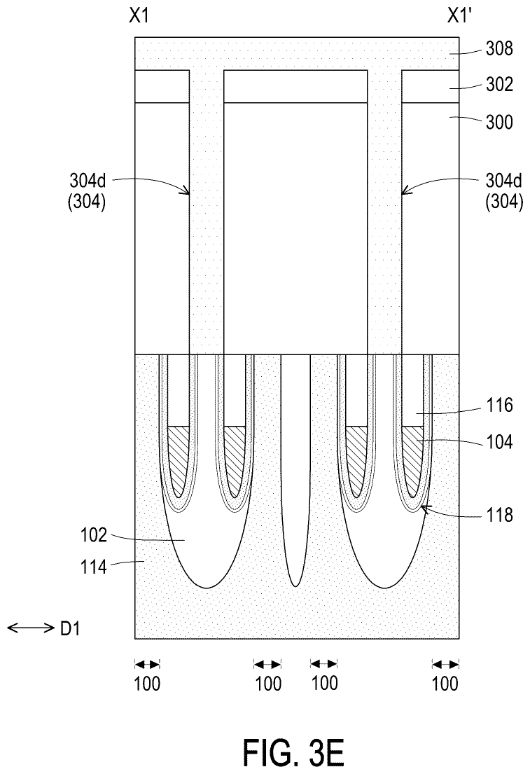

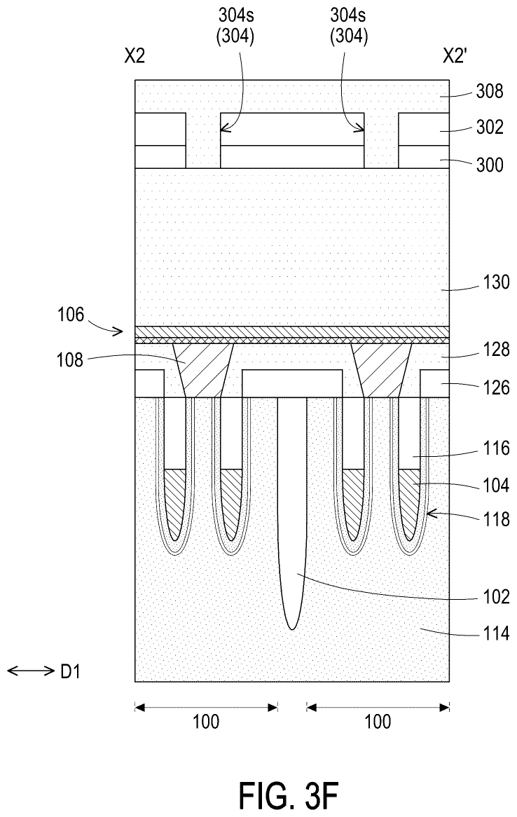

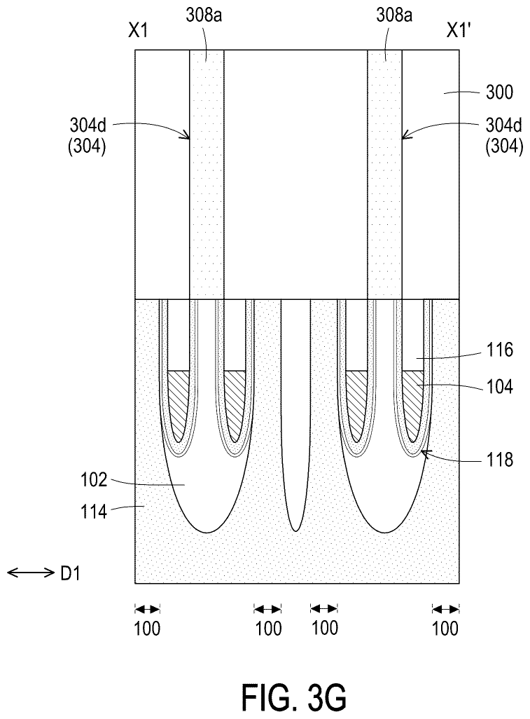

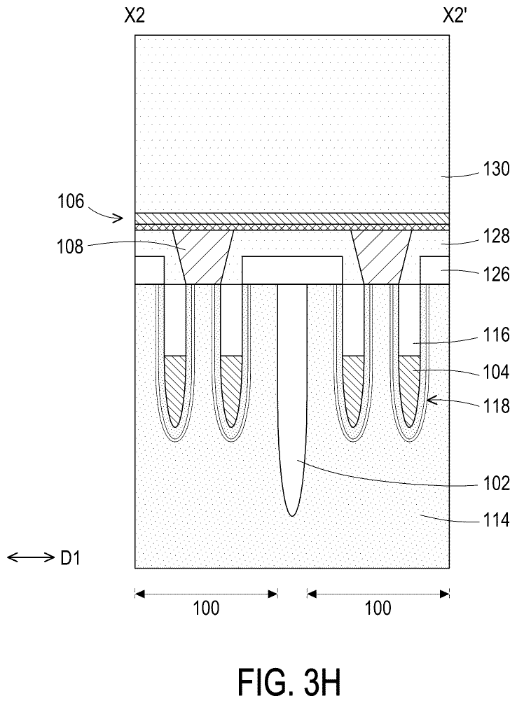

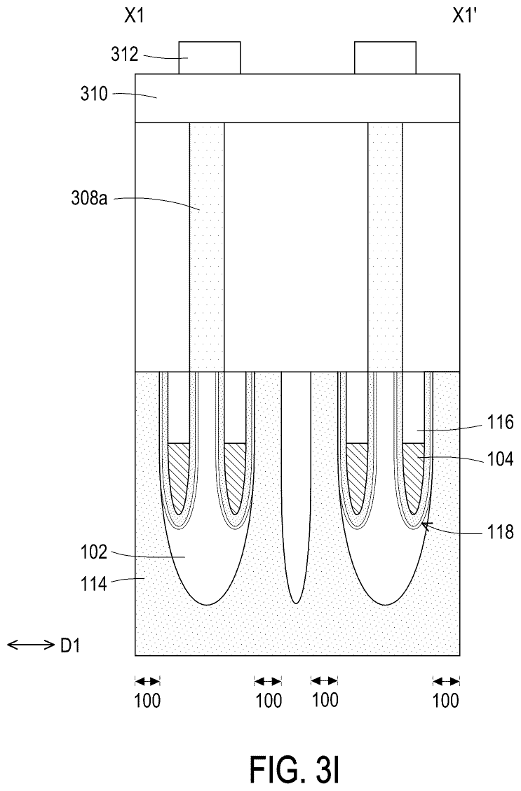

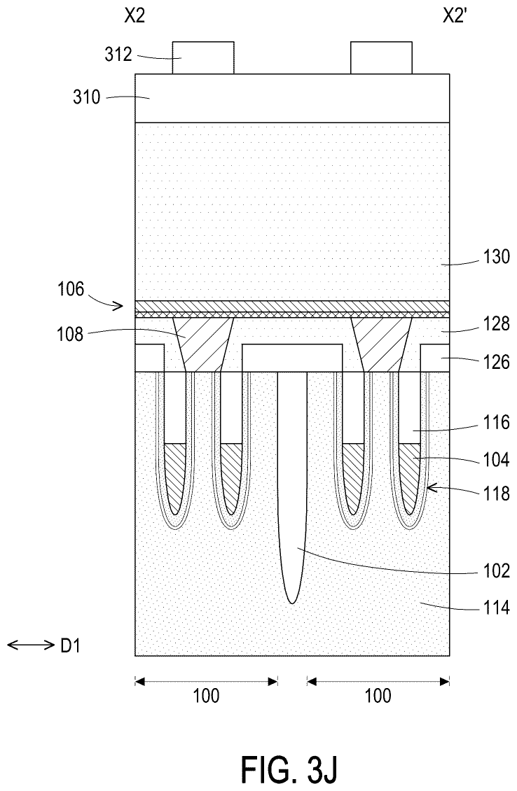

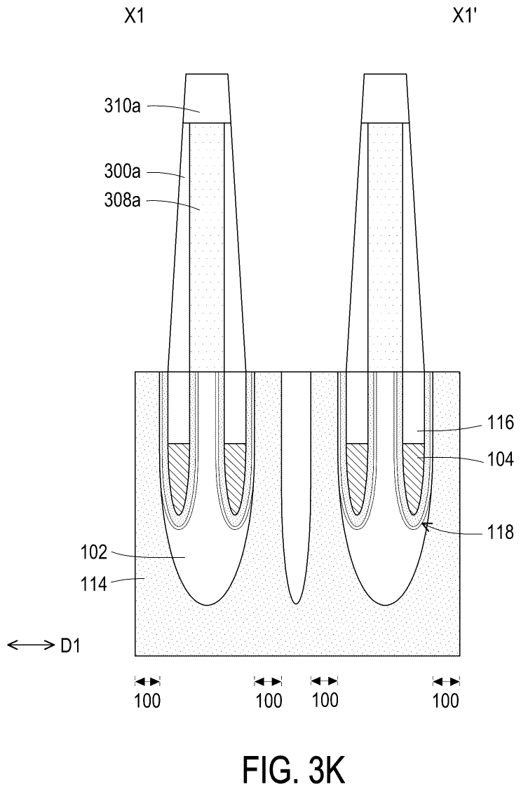

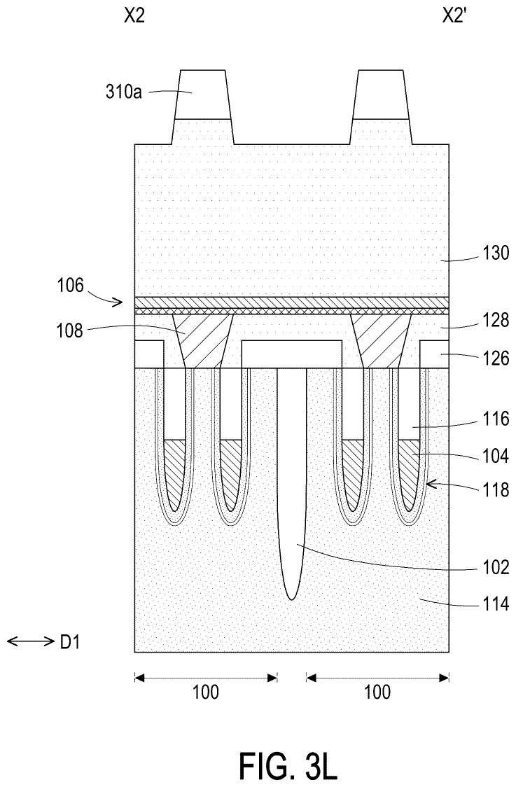

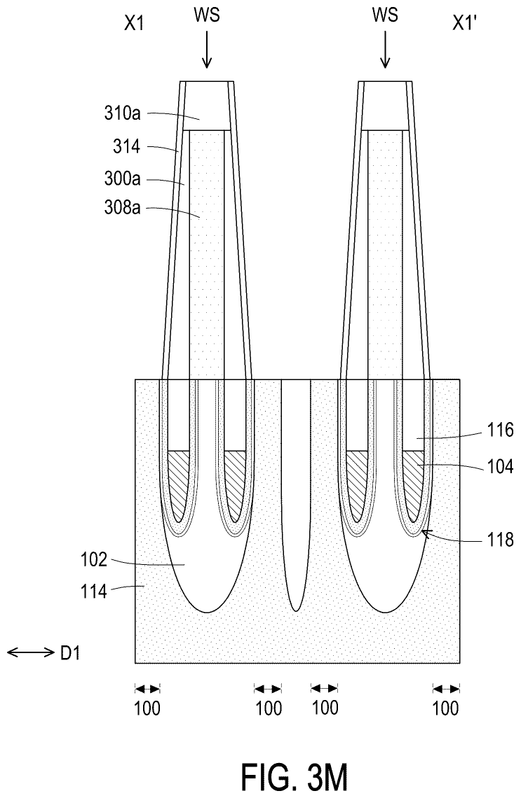

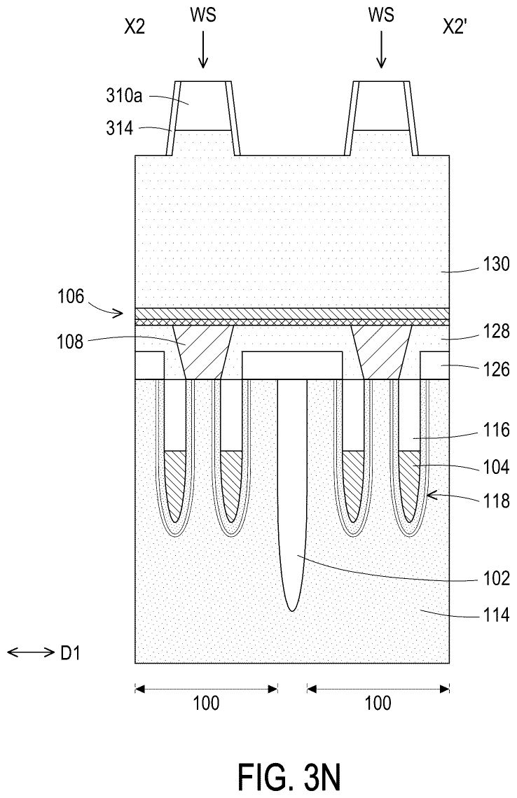

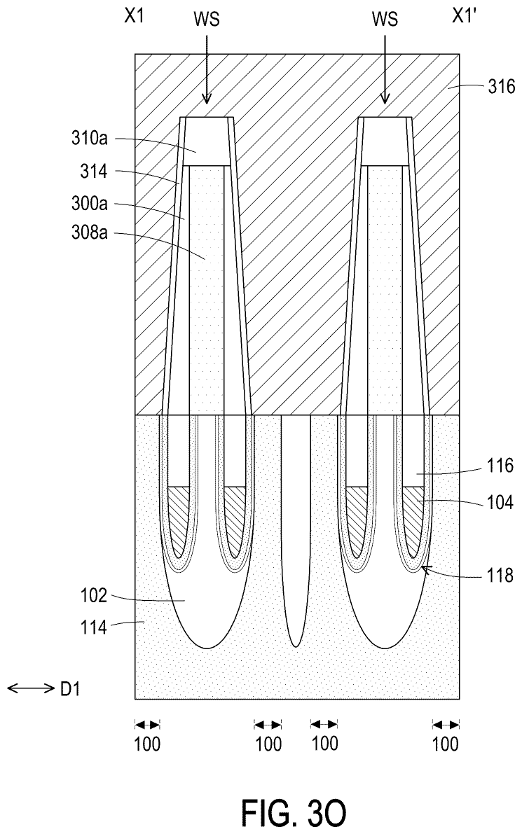

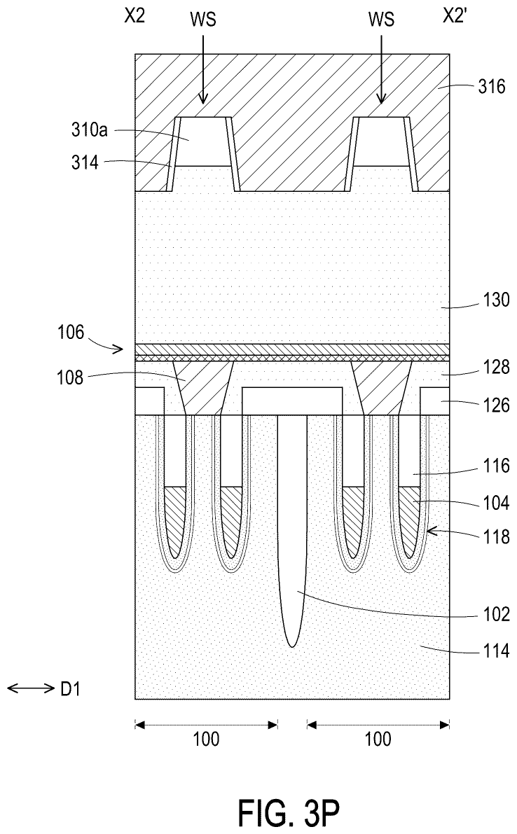

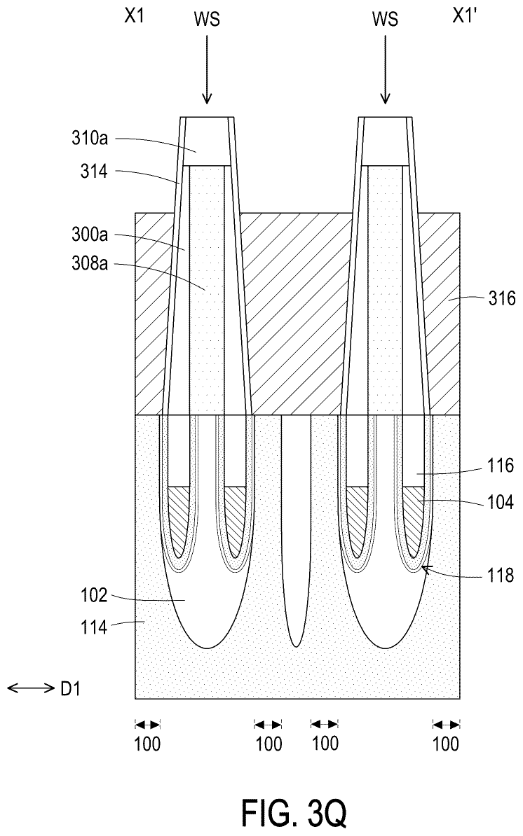

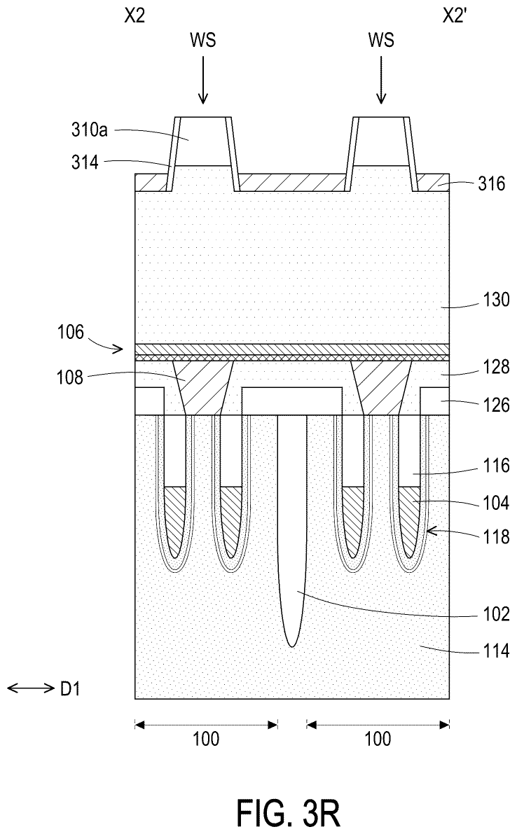

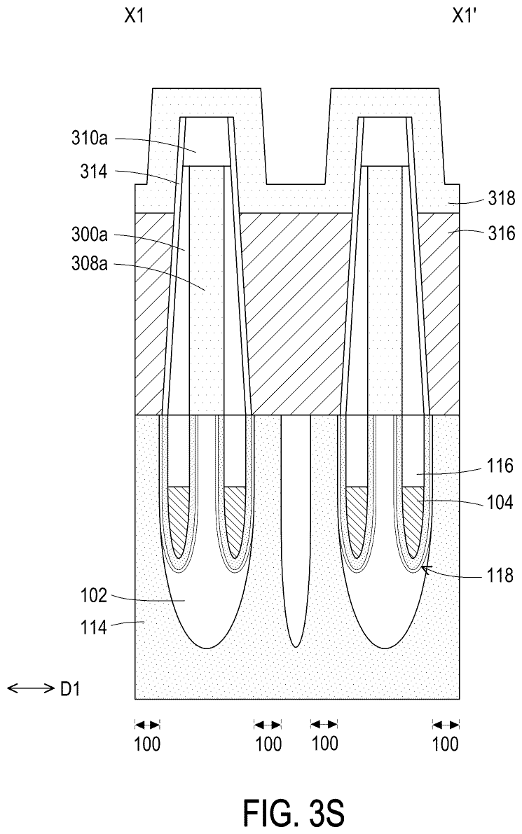

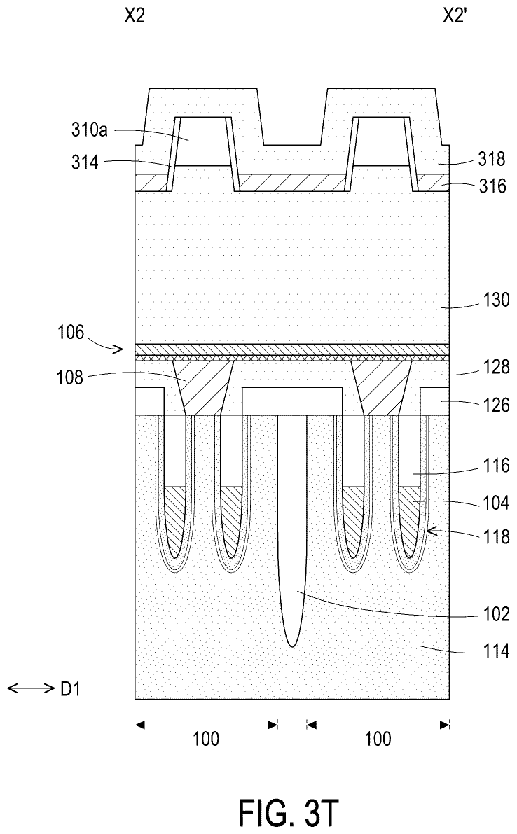

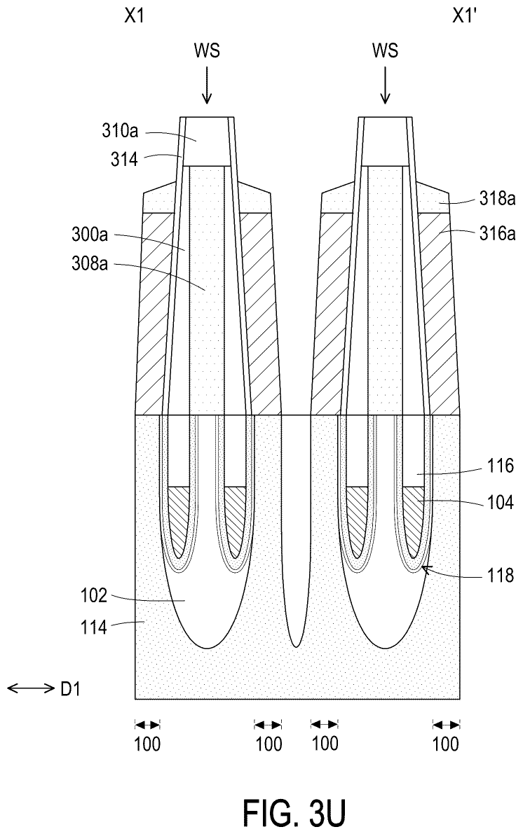

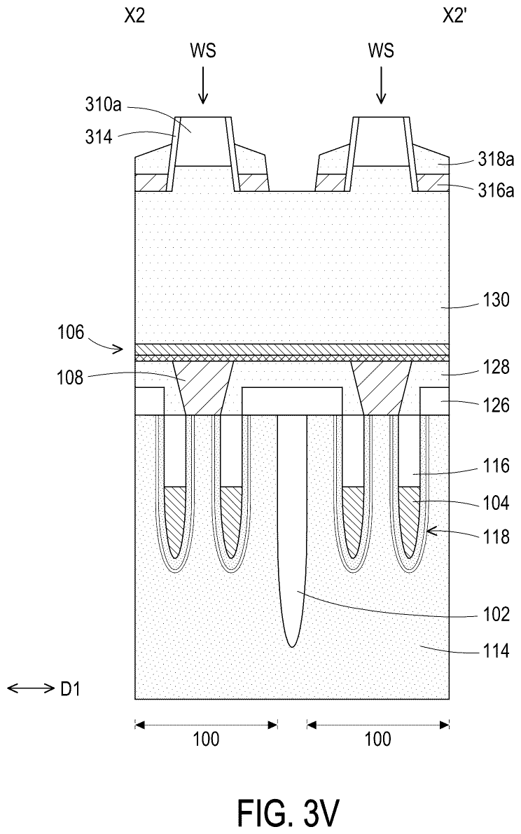

FIG. 2 is a flowchart illustrating a method of forming the structure depicted in FIG. 1A to FIG. 1C according to some embodiments of the disclosure. FIG. 3A to FIG. 3V are schematic cross-sectional views illustrating an intermediate structure during a period in which the method depicted in FIG. 2 is performed. In particular, FIG. 3A, FIG. 3C, FIG. 3E, FIG. 3G, FIG. 3I, FIG. 3K, FIG. 3M, FIG. 3O, FIG. 3Q, FIG. 3S, and FIG. 3U are schematic cross-sectional views taken along the line X1-X1′, respectively, and FIG. 3B, FIG. 3D, FIG. 3F, FIG. 3H, FIG. 3J, FIG. 3L, FIG. 3N, FIG. 3P, FIG. 3R, FIG. 3T, and FIG. 3V are schematic cross-sectional views taken along the line X2-X2′, respectively.

With reference to FIG. 2, FIG. 3A and FIG. 3B, in step S200, an access transistor is formed in the semiconductor substrate 114 and the bit line contact structures 108 and the bit lines 106 are formed on the semiconductor substrate 114 through a series of manufacturing processes. The access transistor may be formed by forming the trench isolation structure 102 in the semiconductor substrate 114 to define an array of the active regions 100, and a plurality of pairs of the word lines 104 (and the surrounding insulation plugs 116 and the gate dielectric layers 118) penetrating the active regions 100 are formed along the direction D2. In addition, along with the formation of the bit line contact structures 108 and the bit lines 106, the insulation patterns 126 and the dielectric layers 128 and 130 described with reference to FIG. 1C are also formed on the semiconductor substrate 114. In addition, the insulation layer 300 is further formed on the semiconductor substrate 114. The insulation layer 300 fills the space between the bit lines 106 and may be formed at a height higher than the height of the dielectric layer 130, so that the dielectric layer 130 is covered by a portion of the insulation layer 300. Besides, a mask layer 302 may be further formed on the insulation layer 300. In some embodiments, the mask layer 302 may have a multi-layer structure.

With reference to FIG. 2, FIG. 3C, and FIG. 3D, in step S202, a plurality of trenches 304 are formed in the current structure. Each trench 304 extends continuously between a pair of the word lines 104 and overlaps the bit line contact structures 108 in one column. A method for forming the trenches 304 includes forming a photoresist pattern 306 on the mask layer 302, where an opening of the photoresist pattern 306 defines positions of the trenches 304, and performing an etching process by applying the photoresist pattern 306 as an etching mask. In addition, the photoresist pattern 306 may be removed by, for instance, performing an ashing process before performing the following operations.

As shown in FIG. 3C and FIG. 3D, the trenches 304 extend on the semiconductor substrate 114 but do not enter the semiconductor substrate 114. In addition, each trench 304 may include a deep portion 304d and a shallow portion 304 alternately arranged along the direction D2. As shown in FIG. 3C, each deep portion 304d overlaps the trench isolation structure 102 and penetrates the mask layer 302 and the insulation layer 300 to reach the top surface of the trench isolation structure 102. On the other hand, as shown in FIG. 3D, each shallow portion 304s overlaps a portion of the active region 100 located between two word lines 104 intersecting the active region 100 and the overlying bit line contact structure 108 and the overlying bit line 106 and penetrates the mask layer 302 and the insulation layer 300 to reach the top surface of the dielectric layer 130. Compared to bottoms of the deep portions 304d, bottoms of the shallow portions 304s are higher than the semiconductor substrate 114.

With reference to FIG. 2, FIG. 3E, and FIG. 3F, in step S204, the trenches 304 are filled with an insulation material 308. In addition to filling the trenches 304, the insulation material 308 may further extend to a top surface of the mask layer 302.

With reference to FIG. 2, FIG. 3G, and FIG. 3H, in step S206, the current structure is planarized until the top surface of the dielectric layer 130 is exposed. Thereby, the insulation material 308, the insulation layer 300, and the mask layer 302 located above the dielectric layer 130 are removed. As a result, the insulation material 308 is patterned to form a plurality of separate insulation structures 308a.

With reference to FIG. 2, FIG. 3I, and FIG. 3J, in step S208, a mask layer 310 and a photoresist pattern 312 are formed on the exposed insulation layer 300 and the dielectric layer 130. In some embodiments, the mask layer 310 may have a multi-layer structure. On the other hand, the photoresist pattern 312 has a plurality of separate bar-shaped portions respectively overlapping a pair of the word lines 104 as well as an insulation structure 308a and a bit line contact structure 108 which are alternately arranged above the pair of the word lines 104, respectively. As shown in FIG. 3I, a width of each bar-shaped portion of the photoresist pattern 312 is greater than a width of the overlapping insulation structure 308a, so that portions of the insulation layer 300 located on both sides of each insulation structure 308a are also covered by the photoresist pattern. 312 covers.

With reference to FIG. 2, FIG. 3K, and FIG. 3L, in step S210, one or more etching processes are performed by applying the photoresist pattern 312 as a mask. Firstly, one portion of the mask layer 310 not covered by the photoresist pattern 312 is removed, and the other portion of the mask layer 310 overlapping the photoresist pattern 312 is kept to form a plurality of bar-shaped hard masks 310a. As shown in FIG. 3K and FIG. 3L, one portion of each hard mask 310a covers one insulation structure 308a and the portions of the insulation layer 300 located on both sides of the insulation structure 308a, and the other portion of each hard mask 310a covers a portion of the dielectric layer 130 overlapping one bit line contact structure 108. In the etching process, as shown in FIG. 3K, one portion of the insulation layer 300 not covered by the hard mask 310a is removed, while the other portion of the insulation layer 300 located on both sides of each insulation structure 308a and covered by the hard mask 310a is kept to form the insulation structure 300a. On the other hand, as shown in FIG. 3L, one portion of the dielectric layer 130 not covered by the hard mask 310a is recessed downward with respect to the other portion of the dielectric layer 130 covered by the hard mask 310a. As a result, a surface of the dielectric layer 130 has protruding structures each respectively overlapping one hard mask 310a. Before the next step is performed, the photoresist pattern 312 is removed by, for instance, performing an ashing process, and the hard mask 310a is left.

So far, a plurality of wall structures WS extending along the direction D2 have been formed on the semiconductor substrate 114 and the dielectric layer 130, and each of the wall structures WS includes one hard mask 310a, the underlying insulation structures 308a and 300a, and the protruding structure of the dielectric layer 130.

With reference to FIG. 2, FIG. 3M, and FIG. 3N, in step S212, multiple pairs of liner layers 314 covering opposite sides of each wall structure WS are formed. Each pair of the liner layers 314 cover the opposite sides of one hard mask 310a and extend to sides of the underlying insulation structure 300a and the underlying protruding structure of the dielectric layer 130. In some embodiments, the liner layers 314 do not extend along a top surface of the wall structure WS (i.e., the top surface of the hard mask 310a) and the surface of the semiconductor substrate 114. Before the liner layers 314 are formed, a cleaning process, e.g., a plasma cleaning process may be performed. During the cleaning process, reactive substances may etch outer insulation structures 300a of the wall structures WS. However, based on the etch selectivity of inner insulation structures 308a of the wall structures WS with respect to the etch selectivity of the outer insulation structures 300a, the inner insulation structures 308a may block the reactive substances and thereby prevent leakage paths that penetrate the wall structures WS from being formed. A method of forming the liner layers 314 may include forming a material layer covering the entire surface by performing a deposition process and removing a horizontal extension portion of the material layer by anisotropic etching, so that the material layer is patterned to form a liner layer 14. In subsequent steps, the liner layers 314 are processed to form the liner layer 124 described with reference to FIG. 1B.

With reference to FIG. 2, FIG. 3O, and FIG. 3P, in step S214, the current structure is covered by a conductor material 316. Specifically, the conductor material 316 may fill up the trench defined between the neighboring wall structures WS and may be further extended above the wall structures WS to cover the hard masks 310a. In some embodiments, the conductor material 316 may be composed of polysilicon. In subsequent steps, the conductor material 316 is thinned down and patterned to form the CC structures 110 described with reference to FIG. 1A and FIG. 1B.

With reference to FIG. 2, FIG. 3Q, and FIG. 3R, in step S216, a height of the conductor material 316 is reduced to be lower than the top surfaces of the wall structures WS, so that the top portions of the wall structures WS and the top portions of the liner layers 314 are exposed. Specifically, the top portions of the hard masks 310a and the top portions of the liner layers 314 protrude from the thinned conductor material 316. In some embodiments, the top surface of the conductor material 316 is currently lower than the top surfaces of the insulation structures 300a and 308a, so that the top portions of the insulation structures 300a and 308a also protrude from the conductor material 316. Furthermore, in some embodiments, a method for thinning down the conductor material 316 includes an etch-back process.

With reference to FIG. 2, FIG. 3S, and FIG. 3T, in step S218, a mask layer 318 is formed on the current structure. The mask layer 318 covers the conductor material 316 and conformally covers portions of the wall structures WS and the liner layers 314 protruding from the conductor material 316. Thereby, the horizontal extension portion of the mask layer 318 extends along the conductor material 316 and the top surfaces of the wall structures WS (i.e., the top surfaces of the hard masks 310a), and a vertical extension portion of the mask layer 318 extends along the surfaces of the liner layers 314 protruding from the conductor material 316.

With reference to FIG. 2, FIG. 3U, and FIG. 3V, in step S220, the mask layer 318 and the conductor material 316 are patterned. One or more anisotropic etching processes may be performed to selectively remove a portion of the mask layer 318 and a portion of the conductor material 316. During etching, the horizontal extension portion of the mask layer 318 covering the top surfaces of the hard masks 310a and the conductor material 316 may be selectively removed at first, and the vertical extension portion of the mask layer 318 covering the liner layers 314 may be at least partially left, so as to form additional hard masks 318a extending in pairs to two opposite sides of each wall structure WS. Subsequently, one portion of the conductor material 316 not covered by the hard masks 318a is selectively removed to expose the underlying structure (e.g., the trench isolation structure 102 shown in FIG. 3U and the dielectric layer 130 shown in FIG. 3V). On the other hand, the other portion of the conductor material 316 overlapping the hard masks 318 is left to form conductor structures 316a located on the two opposite sides of each wall structure WS.

At this time, each wall structure WS and the liner layers 314 and the conductor structures 316a on both sides of the wall structure WS extend continuously along the direction D2. Here, each wall structure WS and the conductor structures 316a on both sides of the wall structure WS have a relatively large height between the neighboring bit lines 106 (as shown in FIG. 3U) and have a relatively small height above the bit lines 106 (as shown in FIG. 3V).

Subsequently, in step S222, a planarization process is performed until the structure above the dielectric layer 130 is removed. The resultant structure is shown in FIG. 1A to FIG. 1C. During the planarization process, the top portion of each wall structure WS (including the top portions of the hard masks 310a, the top portions of the insulation structures 308a and 300a, and the protruding structure of the dielectric layer 130) and the top portions of the liner layers 314 are removed and cut off to form a plurality of portions respectively located between the neighboring bit lines 106. The remaining portions of the wall structures WS and the liner layers 314 form the isolation wall 112 shown in FIG. 1A and FIG. 1B. Here, the remaining portion of the insulation structure 308a forms the inner wall 120 of the isolation wall 112, the remaining portion of the insulation structure 300a forms the outer walls 122 of the isolation wall 112, and the remaining portions of the liner layers 314 form the liner layers 124 of the isolation wall 112. In addition, while the wall structures WS and the liner layers 314 are patterned, the top portions of the conductor structures 316a and the hard masks 318a are removed. As a result, the remaining portions of the conductor structures 316a form the CC structures 110.

Although not shown in the drawings, the storage capacitors may be subsequently formed on the CC structures 110 to form a complete DRAM array.

To sum up, a memory device is provided in one or more embodiments of the disclosure. Each of the memory cells of the memory device arranged in an array respectively includes an access transistor and a storage capacitor. The access transistor of each memory cell is connected to the corresponding storage capacitor through the CC structure. Based on a specific arrangement manner, the CC structures are arranged in pairs and adjoin. Each pair of the neighboring CC structures are connected to the neighboring access transistor and physically and electrically isolation from each other through the isolation wall. Each isolation wall includes the inner wall and the outer walls extending to the two opposite sides of the inner wall. The inner wall has sufficient etch selectivity with respect to the etch selectivity of the outer walls. Even if the etchants or the reactive substances etch the outer walls during manufacturing, the etchants or the reactive substances may be blocked by the inner wall without penetrating the entire isolation wall. Therefore, the electrical isolation between the neighboring CC structures may be guaranteed, and the mutual interference of the adjacent memory cells may be effectively avoided.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a semiconductor substrate, having a first active region and a second active region separated by a trench isolation structure;
a first word line and a second word line, embedded in the semiconductor substrate, wherein the first word line and the second word line are spaced from each other in a first direction and extend along a second direction substantially orthogonal to the first direction and penetrate the first active region and the second active region spaced from each other in the second direction;
a first capacitor contact structure and a second capacitor contact structure, disposed on the semiconductor substrate and located on opposite sides of the first word line and the second word line, wherein the first capacitor contact structure overlaps and is connected to the first active region, the second capacitor contact structure overlaps and is electrically connected to the second active region, and the first capacitor contact structure and the second capacitor contact structure are arranged along the first direction; and
an isolation wall, two opposite sides of the isolation wall contacting the first capacitor contact structure and the second capacitor contact structure, and the isolation wall comprising an inner wall and outer walls covering two opposite sides of the inner wall, wherein an insulation material of the inner wall has etch selectivity with respect to an insulation material of the outer walls.

2. The memory device according to claim 1, wherein the isolation wall overlaps the first word line, the second word line, and the trench isolation structure.

3. The memory device according to claim 1, wherein the isolation wall further comprises a liner layer covering outer surfaces of the outer walls.

4. The memory device according to claim 3, wherein the liner layer of the isolation wall is in direct contact with the first capacitor contact structure and the second capacitor contact structure.

5. The memory device according to claim 3, wherein a top surface of the inner wall, top surfaces of the outer walls, and a topmost portion of the liner layer are substantially coplanar and collectively define a top surface of the isolation wall.

6. The memory device according to claim 1, wherein a top surface of the isolation wall is substantially coplanar with a top surface of the first capacitor contact structure and a top surface of the second capacitor contact structure.

7. The memory device according to claim 1, further comprising:
a first bit line and the second bit line, extending above the semiconductor substrate along the first direction, wherein the first bit line intersects the first active region, and the second bit line intersects the second active region.

8. The memory device according to claim 7, wherein the isolation wall is located between the first bit line and the second bit line.

9. The memory device according to claim 7, wherein a top surface of the first capacitor contact structure, a top surface of the second capacitor contact structure, and a top surface of the isolation wall are higher than a top surface of the first bit line and a top surface of the second bit line.

10. The memory device according to claim 1, wherein the insulation material of the inner wall of the isolation wall comprises silicon nitride, and the insulation material of the outer walls of the isolation wall comprises silicon oxide.

11. A manufacturing method of a memory device, comprising:
forming a trench isolation structure in a semiconductor substrate to define a first active region and a second active region spaced from each other;
forming a first word line and a second word line in the semiconductor substrate, wherein the first word line and the second word line are spaced from each other in a first direction and, along a second direction substantially orthogonal to the first direction, penetrate the first active region and the second active region spaced from each other in the second direction;
forming a first capacitor contact structure and a second capacitor contact structure on the semiconductor substrate, wherein the first word line and the second word line extend between the first capacitor contact structure and the second capacitor contact structure, the first capacitor contact structure overlaps and is connected to the first active region, the second capacitor contact structure overlaps and is connected to the second active region, and the first capacitor contact structure and the second capacitor contact structure are arranged along the first direction; and
setting an isolation wall on the semiconductor substrate, wherein two opposite sides of the isolation wall contact the first capacitor contact structure and the second capacitor contact structure, the isolation wall includes an inner wall and outer walls covering two opposite sides of the inner wall, and an insulation material of the inner wall has etch selectivity with respect to an insulation material of the outer walls.

12. The manufacturing method according to claim 11, wherein the step of forming the isolation wall comprises:
forming an initial isolation wall continuously crossing the first active region and the second active region along the second direction; and
patterning the initial isolation wall to remove one portion of the initial isolation wall overlapping the first active region and the second active region, wherein the other portion of the initial isolation wall between the first active region and the second active region is retained to form the isolation wall.

13. The manufacturing method according to claim 12, wherein the step of forming the initial isolation wall comprises:
forming an inner insulation structure;
forming an outer insulation structure covering two opposite sides of the inner insulation structure and forming a hard mask located on the inner insulation structure and the outer insulation structure; and
forming a liner layer covering the outer insulation structure and a side of the hard mask.

14. The manufacturing method according to claim 13, wherein the step of patterning the initial isolation wall comprises removing the hard mask and removing a top portion of the inner insulation structure, a top portion of the outer insulation structure, and a top portion of the liner layer, a remaining portion of the inner insulation structure forms the inner wall, a remaining portion of the outer insulation structure forms the outer walls, and a remaining portion of the liner layer covers sides of the outer walls.

15. The manufacturing method according to claim 11, before forming the first capacitor contact structure, the second capacitor contact structure, and the isolation wall, the manufacturing method further comprising:
forming a first bit line contact structure and a second bit line contact structure on the semiconductor substrate, wherein the first bit line contact structure overlaps and is connected to a portion of the first active region located between the first word line and the second word line, and the second bit line contact structure overlaps and is connected to a portion of the second active region located between the first word line and the second word line; and
forming the first bit line and the second bit line extending along the first direction on the semiconductor substrate, wherein the first bit line is connected to the first active region through the first bit line contact structure, and the second bit line is connected to the second active region through the second bit line contact structure.

16. The manufacturing method according to claim 15, wherein the first capacitor contact structure and the second capacitor contact structure are located between the first bit line and the second bit line, and the isolation wall is located between the first bit line contact structure and the second bit line contact structure.
